(19) United States
(12) Patent Application Publication
(10) Pub. No.: US 2015/0221847 A1
(43) Pub. Date: Aug. 6, 2015

(54) SEEBECK RECTIFICATION ENABLED BY INTRINSIC THERMOELECTRIC COUPLING IN MAGNETIC TUNNELING JUNCTIONS

(71) Applicant: The University of Manitoba, Winnipeg (CA)

(72) Inventors: Can-Ming Hu, Winnipeg (CA); Yongsheng Gui, Winnipeg (CA); Zhaohui Zhang, Winnipeg (CA); Hong Guo, Winnipeg (CA)

(21) Appl. No.: 14/420,000

(22) PCT Filed: Jan. 18, 2013
(86) PCT No.: PCT/IB2013/000452

§ 371 Date: Feb. 6, 2015

Related U.S. Application Data
(60) Provisional application No. 61/682,041, filed on Aug. 10, 2012.

(51) Int. Cl. H01L 35/32; G01N 22/02; H01L 43/10; H01L 35/22; H01L 35/04; H01L 43/02

(52) U.S. Cl. CPC H01L 35/32; H01L 35/04; H01L 43/02; H01L 43/10; H01L 35/22; G01N 22/02

(57) ABSTRACT

Embodiments of intrinsic magneto-thermoelectric transport in MTJs carrying a tunneling current/in the absence of external heat sources are presented. In one embodiment Ohm's law for describing MTJs may be revised even in the linear transport regime. This has a profound impact on the dynamic response of MTJs subject to an ac electric bias with frequency ω, as demonstrated by a novel Seebeck rectification effect measured for ω up to microwave (GHz) frequencies. This Seebeck rectification effect may be employed in magneto-thermoelectric devices.

### CROSS-REFERENCE TO RELATED APPLICATIONS

This application claims priority to U.S. Provisional Patent Application Ser. No. 61/682,041, filed Aug. 10, 2012, which is incorporated by reference herein in its entirety.

### BACKGROUND

1. Field of the Invention

This invention relates to thermoelectronics and more particularly relates to Seebeck Rectification Enabled by Intrinsic Thermoelectric Coupling in Magnetic Tunneling Junctions. This invention also relates to sensors and imaging applications based on such Rectification.

2. Description of the Related Art

The new discipline of spin caloritronics has received much attention recently and made the renaissance of thermoelectricity in spintronic devices and magnetic structures. Experimental breakthroughs have been achieved mainly by studying the static thermoelectric response in spintronic circuits involving metals with different thermoelectric properties. Very recently, in a ferromagnet-oxide-silicon tunneling structure, intriguing Seebeck spin tunneling has been demonstrated. In addition, in a few experiments performed on metallic magnetic tunneling junctions (MTJ) subject to external heating, it was found that the MTJ can be characterized by an absolute thermal power S which can be magnetically controlled. From a historical perspective, deep insight into the thermoelectricity was not achieved until William Thomson investigated the intrinsic thermoelectric transport of a current flowing in a conductor characterized by S, whereby he conceived the concept of Thomson heat pivotal for understanding thermoelectricity.

### SUMMARY OF THE INVENTION

Embodiments of intrinsic magneto-thermoelectric transport in MTJs carrying a tunneling current I in the absence of external heat sources are presented. In one embodiment Ohm's law for describing MTJs may be revised even in the linear transport regime. This has a profound impact on the dynamic response of MTJs subject to an AC electric bias with frequency ω, as demonstrated by a novel Seebeck rectification effect measured for ω up to microwave (GHz) frequencies.

Embodiments of a thermoelectric device are described. For example, in one embodiment the thermoelectric device comprising a Magnetic tunneling Junctions (MTJ) is patterned from a wafer which may include a substrate and a ferromagnetic multilayer structure grown on the substrate, the MTJ comprising a plurality of thermoelectric layers configured such that a non-linearity between a tunneling current (I) and a voltage (V) on the MJT is induced by heat dissipation of the tunneling current which modifies a voltage profile of the MJT via thermoelectric coupling, such that a measurement of a Seebeck coefficient S exhibited by the MTJ is provided without requiring an external heating source.

In one embodiment, the MJT comprises a plurality of Thomson Thermoelectric Conductor (TTC) elements. At least two of the plurality of thermoelectric layers may include ferromagnetic layer such as CoFeB. At least one of the plurality of thermoelectric layers may include tunneling barrier layer such as MgO. In one embodiment, a thermoelectric device comprises substrate such as Si and glass and a ferromagnetic multilayer structure grown on the substrate.

The term “coupled” is defined as connected, although not necessarily directly, and not necessarily mechanically.

The terms “a” and “an” are defined as one or more unless this disclosure explicitly requires otherwise.

The term “substantially” and its variations are defined as being largely but not necessarily wholly what is specified as understood by one of ordinary skill in the art, and in one non-limiting embodiment “substantially” refers to ranges within 10%, preferably within 5%, more preferably within 1%, and most preferably within 0.5% of what is specified.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Other features and associated advantages will become apparent with reference to the following detailed description of specific embodiments in connection with the accompanying drawings.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of specific embodiments presented herein.

FIG. 1 illustrates a Thomson Thermoelectric Conductor (TTC) connected in (a) an open circuit, (b) a closed circuit, and (c) a closed circuit with a supporting material; and (e)(f)(g) illustrate the corresponding temperature profiles of the TTC; (d) illustrates a schematic MTJ circuit; and (h) illustrates an MTJ structure adaptable according to the present embodiments.

FIG. 2 illustrates embodiments of (a) Asymmetric and (b) symmetric combination of the dc voltage V+ and V₋ measured on sample A with a positive and negative tunneling current I, respectively; (c) and (d) are the same as (a) and (b) but measured on sample B; circles and squares are measured at the AP and P alignments of the MTJ, respectively.

FIG. 3 illustrates (a) the 1st and (b) the 2nd harmonic voltage measured on sample B with a low-frequency ac tunneling current, as well as the Seebeck rectification voltage V, measured with the microwave tunneling current being (c) modulated and (d) in continuous wave; circles and squares are measured at AP and P alignments, respectively.

FIG. 4 illustrates the TMR of sample A measured as a function of (a) the external magnetic field strength and (b) the field direction; while the Seebeck rectification voltage measured at ω/2π=10.0 GHz is also illustrated as a function of (c) the external magnetic field strength and (d) the field direction.

FIG. 5 illustrates (a) The resistance of an MTJ as a function of the magnetic field and its sweeping direction. The dc current bias is 10 μA. The MTJ is patterned in an elliptical shape with long and short axes of 190 and 100 nm, respectively. (b) The Seebeck rectification measured at ω/2π=10 GHz as a function of the magnetic field. The incident microwave power injected into the MTJ is −25 dBm (˜3.2 μW) after the power calibration. (c) The Seebeck rectification Vᵣ (symbols) as a function of the microwave power P_{MW}, which appears as a linear relation indicated by the solid lines.

FIG. 6 illustrates (a) A schematic of the experimental set-up. Simulated (b) and experimental (c) results of the microwave field amplitude by COMSOL Multiphysic at ω/2π=6 GHz. The black area in (b) shows the position of the horn antenna. For comparison the imaged area is indicated by the dotted lines in (b).

FIG. 7 illustrates (a) Microwave reflection imaging of a hidden Al disc with a diameter of 7.12 cm. (b) Microwave reflection imaging of a hidden Al disc with a diameter of 5.08 cm. (c) Microwave reflection imaging of a hidden acetal disk with a diameter of 7.12 cm. (d) Schematic view of the measurement system. The dotted lines indicate the position of the hidden objects and the frequency of the measurement is ω/2π=10.5 GHz.

### DETAILED DESCRIPTION

Various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only, and not by way of limitation. Various substitutions, modifications, additions, and/or rearrangements within the spirit and/or scope of the underlying inventive concept will become apparent to those skilled in the art from this disclosure.

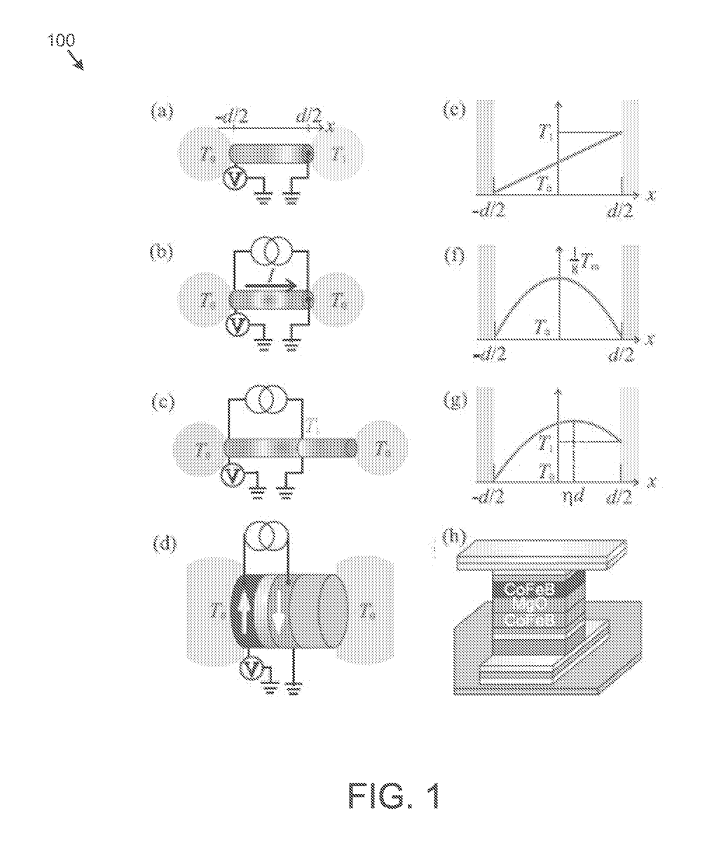

Embodiments of a Thomson Thermoelectric Conductor (TTC) with both particle (J) and heat (J_{Q}) flux densities are shown in FIG. 1. The total energy flux density in the TTC is J_{W}=J_{Q}+ μ̅J, where J, J_{Q}, and J_{W} satisfy the Onsager reciprocal relations and the energy conservation principle

J=−(σ/e²)∇ μ̅+(Sσ/|e|)∇T,

J_{Q}=(TSσ/|e|)∇ μ̅−(κ+TS²σ)∇T,

C_{ν}∂T/∂t+∇·J_{W}=0.

Here, σ and κ are the electric and thermal conductivity, respectively, C_{ν} is the specific heat per unit volume, and μ̅=μ−eV is the electrochemical potential.

Taking the simplest case of a one dimensional TTC with a length d as shown in FIG. 1(a) for example. In an open electric circuit and connecting the TTC to two thermal reservoirs with different temperatures T₀ and T₁, the steady state solution of Eq. 1 gives V=S(T₁−T₀) and T(x)=(T₀+T₁)/2+(T₁−T₀)x/d, as plotted in FIG. 1(e). In certain embodiments, this may demonstrate an embodiment of the Seebeck effect.

In a closed circuit carrying a continuous electric current with the current density i=−|e|J, if the TTC is set in a symmetric thermal environment as shown in FIG. 1(b), then the steady state solution depends on the boundary conditions at the contacts. In the case the thermoelectric heating/cooling dominates over both Joule and conductive heating in the contacts, the result may be an embodiment of the Peltier effect. On the other hand if the thermoelectric effect is weak, the solution leads to T(x)=T₀−[(x/d)²−¼)]Tₘ/2, with Tₘ≡(i²d²)/(κσ). The maximum temperature is located at the center of the TTC, as plotted in FIG. 1(f).

The position of the maximum temperature shifts by an amount of ηd if the TTC is set in an asymmetric thermal environment, for example by connecting the TTC to the thermal reservoir at one side via a supporting material as shown in FIG. 1(c). The thermal asymmetric parameter η can be calculated by solving Eq. 1 to determine the temperature distribution T(x). In the case shown in FIGS. 1(c) and (g), it is easy to show that η=(T₁−T₀)/Tₘ.

Such a TTC may be a building block of an embodiment of a model for highlighting the intrinsic thermoelectric transport in a MTJ. As shown in FIGS. 1(d) and (h), the model is a multilayered MTJ as a series of the TTC's with a cross-sectional area A. The model carries the tunneling current I=iA, and is connected to the thermal reservoir directly on the one side but via an insulating substrate on the other side. By solving Eq. 1 at the steady state condition ∂T/∂t=0, the model may be represented as:

V(I)=R·I+S·Σ(ηⱼR_{κj}Rⱼ)·I²,

where R≡ΣRⱼ is the resistance of the junction, S≡Σ(ηⱼR_{κj}RⱼSⱼ)/Σ(ηⱼR_{κj}Rⱼ) is the Seebeck coefficient of the MTJ defined based on the TTC model, which is related to the resistance Rⱼ=dⱼ/(σⱼA), the heat resistance R_{κj}=dⱼ/(κⱼA), the thermal asymmetric parameter ηⱼ, and the absolute thermal power Sⱼ of the j-th layer that carries the tunneling current I.

Equation 2 shows that the tunneling current I in a MTJ, makes not only a 1st order contribution to the voltage V via Ohm's law, but also induces a 2nd order contribution. Such an I-V non-linearity is intrinsically induced by the heat dissipation of the tunneling current, which modifies the voltage profile of the MTJ via the thermoelectric coupling. It enables measuring the Seebeck coefficient S even without using any external heating sources such as lasers. In the context of linear response, the induced nonlinear term in the I-V relation is similar to the textbook example of the correction to Ohm's law via the anisotropic magnetoresistance (AMR) of magnetic materials, since both are determined by the coupled effect of a pair of forces which drive the linear response via the Onsager reciprocal relation. Hence, such an intrinsic coupling effect should not be ignored even in the linear transport regime. Other conventional nonlinearity caused by either ∂S/∂T or ∂R/∂T can be added to Eq. 2 as additional higher order corrections if necessary. It should also be noted that the extrinsic effects such as asymmetric tunneling probability in an MTJ may also introduce addition I² terms in Eq. (2), which can result in similar microwave rectification effect.

The MTJ structures we measured may be fabricated on a plurality of wafers grown under different conditions in a plurality of different groups. For example, a first wafer (wafer A) may be grown on a Corning glass substrate with the buffer and capping layer of Ta(5)/Ru(18)/Ta(3) and Ru(5)/Ta(5)/TiWN(15), respectively. The MTJ structure includes (in nanometers) PtMn(18)/CoFe(2.2)/Ru(0.9)/CoFeB(3)/MgO(0.7)/CoFeB(3). The bottom and top CoFeB layers act as a pinned and a free magnetic layer, respectively, and an average resistance-area product of RA≈170 Ωμm² may be found for parallel magnetic alignment. A second wafer (wafer B), with an average RA≈10 Ωμm², may be grown on Si substrate covered with 200 nm SiO₂, which include PtMn(20)/CoFe(2.27)/Ru(0.8)/CoFeB(2.2)/CoFe(0.525)/MgO(1.2)/CoFeB(2.5). The buffer and capping layer may be TaN and Ta, respectively. These multilayer structures may be further patterned into different dimensions. For proof of concept, a set of eight microstructured samples from the wafer A and eight nanostructured samples from the wafer B were systematically measured in four different experiments performed at room temperature. Typical results of one sample from each wafer are included herein to highlight significant observations. Sample A (No. R07C6) from the wafer A has the dimension of 2 μm×4 μm. Sample B (No. 652-14) from the wafer B has an elliptical shape with the long and short axis of 204 and 85 nm, respectively. The long axes of sample A (B) are perpendicular (parallel) to the pinning direction.

A dc transport experiment was performed to confirm Eq. 2. A small (up to a few tens of mT) in-plane magnetic field is applied to set the magnetization in the free and pinning layer either in parallel (P) or anti-parallel (AP) alignments. By connecting the electrode at the pinning layer side to the electric ground, the dc measurements are performed by changing the polarity of the tunneling current I from positive to negative, and by measuring the corresponding voltage V₊ and V₋ at the electrode of the free layer side using a dc voltage meter. The 1st and 2nd order terms in Eq. 2 can be deduced, respectively, from the asymmetric and symmetric voltage combinations via the relations (V₊+V₋)/2=IR and (V₊+V₋)/2=SΣ(ηⱼR_{κj}Rⱼ)I².

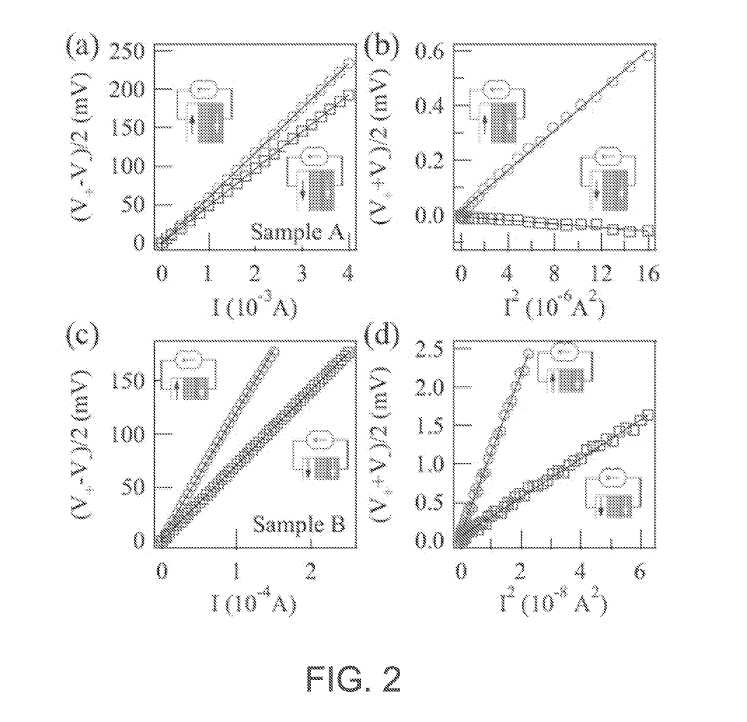

As shown in FIGS. 2(a) and (c), by fitting the results of (V₊+V₋)/2 to Eq. 2, and by subtracting a field-independent contact resistance of about 18 (6) Ω for sample A (B) determined from a controlled experiment comparing two- and four-terminal measurements, the junction resistance R is determined to be R_{P} (R_{AP})=30.2 (40.7) and 710 (1250) Ω for sample A and B, respectively, which correspond to a tunneling magneto-resistance (TMR) ratio of 35% and 76%. By using the materials parameters for the MTJ structure, Σ(ηⱼR_{κj}Rⱼ) in P (AP) alignments is calculated to be 0.9(0.2)×10⁵ and 1.1(2.0)×10⁹Ω·K/W for sample A and B, respectively.

According to Mott's law the Seebeck coefficients are proportional to the energy derivative of the electric conductance at the Fermi energy. Since the conductances differ for P and AP alignments, their energy derivatives and thus the Seebeck coefficients should differ as well. Indeed, fitting the (V₊+V₋)/2 data shown in FIGS. 2(b) and (d) to Eq. 2, the Seebeck coefficient in P (AP) alignments is determined as S_{P} (S_{AP})=−37 (280), and 22 (53) μV/K for sample A and B, respectively.

Although the values of Σ(ηⱼR_{κj}Rⱼ) for the two sets of samples differ by about four orders of magnitude due to their different cross-sectional areas and MgO thicknesses, the magnitude of the Seebeck coefficients measured in both sets of samples are found comparable with the results of ab initio calculations. This indicates that Eq. 2 captures the key feature of the intrinsic thermoelectric coupling, based on which we proceed to study the dynamic effects.

As mentioned, Eq. 2 resembles the AMR effect known for its significance in magnetism research and spintronic applications. In particular, AMR enables the powerful spin rectification effect which utilizes resonant magnetization dynamics of ferromagnetic metals. Similarly, it was demonstrated that the intrinsic thermoelectric coupling dominates the dynamic response of the MTJ, which leads to novel broadband Seebeck rectification and 2nd harmonic generation.

Under the dynamic bias when the MTJ carries a time-dependent tunneling current of I(t)=I₀ cos(ωt), the exact solution of Eq. 1 is very complicated, since the time-dependent temperature distribution involves a series of infinite terms each with a different time constant. However, in the limit of ωτ>>1, i.e., when the thermal relaxation time τ of the TTC and its supporting materials is much longer than the period of the ac bias, the slow thermodynamics falls far behind the rapid electrodynamics, so that we may take the quasi-equilibrium approximation by assuming the TTC is effectively heated by an average power of I₀²/2σ. In this case, the solution of Eq. 1 is simplified and we find

V(t)=Vᵣ+V_{ω}cos(ωt)+V_{2ω}cos(2ωt).

The 2nd term of Eq. 3 is Ohm's law in its dynamic form with V_{ω}=I₀R. The 1st and the 3rd terms reveal the Seebeck rectification and 2nd harmonic voltage, respectively, where V_{T}=V_{2ω}=SΣ(ηⱼR_{κj}Rⱼ)I₀²/2 are proportional to the Seebeck coefficient (but ηⱼ may be frequency dependent and hence be different from the dc values in Eq. 2. Note the Seebeck rectification introduced in Eq. 3 describes the microwave photovoltage generated by the intrinsic thermoelectric coupling of MTJs, which distinguishes from the spin rectification induced by spin dynamics.

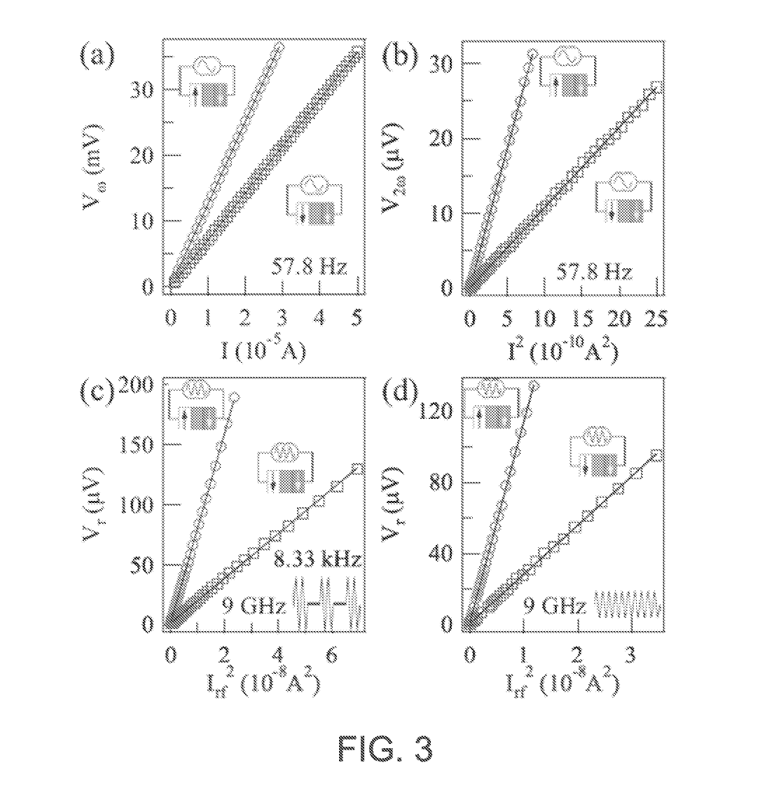

Thus the dynamic transport experiment may be performed to confirm Eq. 3. For ω up to 10 kHz, V_{ω} and V_{2ω} are directly measured by using a lock-in amplifier to send an ac current of I(t)=I₀ cos(wt) to the MTJ with I₀ up to 4 mA. This elegant technique was recently established for studying the spin Seebeck effect in lateral spin caloritronic devices. As shown in FIG. 3(a) for sample B, the current dependence of V_{ω} measured at ω/2π=57.8 Hz agrees with the asymmetric dc voltage (V₊−V₋)/2 plotted in FIG. 2(c). The fact that both voltages follow Ohm's law with the same tunneling resistance confirms this finding. Additionally, the 2nd harmonic voltage V_{2ω} directly measured at both P and AP alignments as shown in FIG. 3(b), which shows the similar power (I₀²) dependence as the symmetric dc voltage (V₊−V₋)/2 plotted in FIG. 2(d). This indicates that they have the same origin as predicted by Eqs. 2 and 3.

Further, it is shown in the modulated microwave measurements that the Seebeck rectification voltage can be generated by MTJs at ω up to GHz frequencies. In such a high frequency regime, a microwave generator may be used to directly send the high-frequency ac current I_{rf} to the MTJ via a coaxial cable, and measure V_{T} by using a lock-in amplifier and modulating the microwave power at 8.33 kHz with a square wave. Embodiments of this technique may be used for studying spin rectification. V_{T} measured in such an accurate way at both P and AP alignments of the sample B is shown in FIG. 3(c) at ω/2π=9.0 GHz. Here, I_{rf} is estimated from the incident average microwave power P_{avg} via the relation P_{avg}=(R+Z₀)²I_{rf}²/16Z₀, which takes into account the impedance mismatch of the MTJ with the coaxial cable (Z₀=50Ω). The dependence of V_{T} on I_{rf} may be very similar to V_{2ω} shown in FIG. 3(b).

To ensure that the modulation of the microwave power at 8.33 kHz would not induce any spurious effects in measuring the Seebeck rectification, a 4th experiment using continuous wave (CW) microwave measurements was performed. Here, V_{T} is directly measured by using a dc voltage meter, at a constant incident microwave power P. Without modulation P=(R+Z₀)²I_{rf}²/8Z₀, V_{T} measured in such a direct way as shown in FIG. 3(d) is found in fairly good agreement with that of FIG. 3(c). Hence, by comparing the results shown in FIGS. 2 and 3 measured independently in four different experiments, we conclude that the dc correction to Ohm's law as shown in FIGS. 2(b) and (d), the dynamic 2nd harmonic generation as shown in FIG. 3(b), and the Seeback rectification as shown in FIGS. 3(c) and (d), can all be consistently explained by Eqs. 2 and 3. Therefore, the curious nature of the intrinsic thermoelectric coupling of the MTJ is unambiguously revealed.

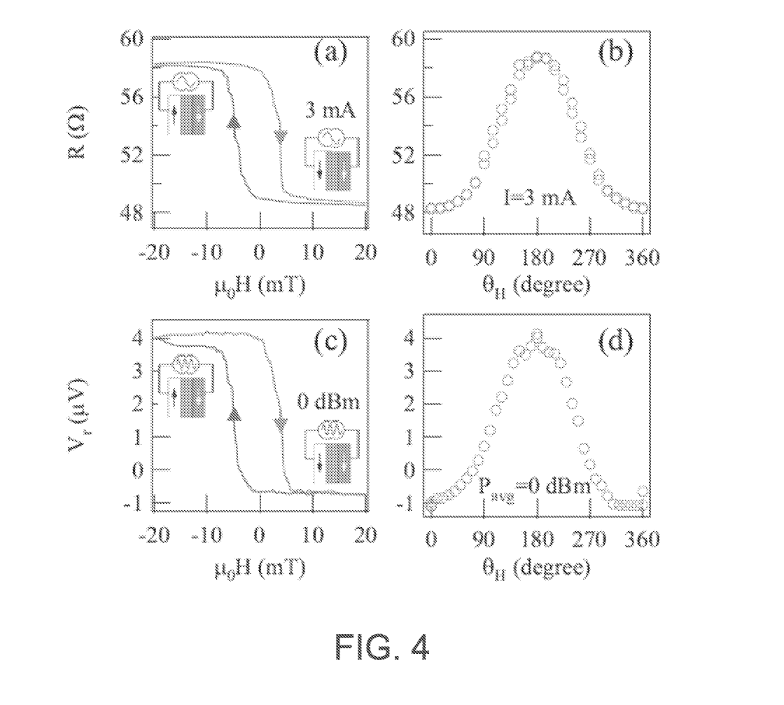

Since V_{T} is found to be magnetic state dependent indicates that the Seebeck rectification of MTJs can be magnetically controlled, which can be demonstrated more clearly in two additional experiments. FIGS. 4(a) and (b) show the TMR of the sample A measured at 384 Hz as a function of the field strength (H) and the direction (θ_{H}) of the in-plane external magnetic field H, respectively. R(H) in FIG. 4(a) is taken at θ_{H}=0°, while R(θ_{H}) in FIG. 4(b) is measured at H=10 mT. The results are characteristic for MTJs showing that the TMR is determined by the relative direction of the magnetizations of the pinned and free layers. This has been so-far the foundation of the applications of MTJs. In FIGS. 4(c) and (d), we plot the H and θ_{H} dependence of the Seebeck rectification V_{T} measured at ω/2π=10.0 GHz. Clearly, V_{T} is also magnetically controlled. Note that since V_{T} depends on S which may change sign at different magnetization alignments, in contrast to the always positive TMR, the polarity of V_{T} can also be magnetically controlled, as shown in FIGS. 4(c) and (d).

Finally, the intriguing Seebeck rectification with the spin-torque diode is compared. While both can generate microwave photovoltages in MTJs, the spin-torque diode is based on the narrow band spin rectification effect in which the magnetization is resonantly driven by either microwave magnetic field or spin torque. In contrast, Seebeck rectification is a broadband effect induced by thermoelectric coupling. In the nano-structured set of samples of the wafer B, a comparable power sensitivity of about 7 and 8˜14 μV/μW for spin and Seebeck rectification, respectively. Such a high sensitivity makes the Seebeck rectification a potentially powerful new approach for electrically investigating thermal spin transfer torques, in a way similar as the spin rectification in the study of spin transfer torques. Most excitingly, it forms new ground for utilizing spin caloritronics in high-frequency applications, which might enable harnessing the usually wasted thermal energy in MTJs.

Electromagnetic waves at microwave frequencies can penetrate optically opaque and non-conducting materials and interact with subsurface structures in addition to structures on the surface of the material. This subsurface imaging allows embedded defects and/or hidden objects to be non-destructively detected by viewing the contrasting dielectric properties of the defect and the surrounding structure. As microwave radiation under power limited by the regulation is non-ionizing and has not been shown to cause any long-term damage to human tissue, microwave imaging techniques have significant potential for medical imaging technology.

Traditionally, microwave imaging systems measure the spatial distribution of scattered fields using an antenna or an antenna array and reconstruct the image using various algorithms. The main challenge in the experimental implementation of these traditional systems is the design and fabrication of satisfactory transmitting and receiving antennas, which are required to have high directivity, a wide impedance bandwidth, and minimal size. The most problematic requirement is the size of the antenna, which is related to the operating frequency range and for microwave imaging results in antenna dimensions on the order of centimetres and decimetres. This large size severely limits the resolution of these systems, as the high magnitude cross-talk patterns produced when antennas are placed near to each other will result in fairly low sensor densities on any detector array produced.

Advances in spintronic techniques have made spintronic sensors a promising alternative to traditional microwave sensors for microwave imaging. One of the major advances is the discovery that a microwave signal can be rectified to a dc signal in a ferromagnetic material via the non-linear coupling between the microwave field and the material's dynamic magnetization. Spintronic sensors possess dual advantages over antenna sensors in both their small size and their experiment-friendly de-voltage output which can be used for signal processing. The sensitivity of spintronic sensors (which is characterized by the ratio between the produced dc voltage and the incident microwave power) has been significantly improved by the development of microwave technology and nano-fabrication techniques. Estimations and recent experimental results have found that at ferromagnetic resonance the sensitivity of spin-diode based magnetic tunnel junctions (MTJs) may exceed 1000 mV/mW, which makes it very interesting for practical applications in microwave measurement technology. Note that in contrast to any conventional semiconductor sensors, the spintronic sensor can detect not only the electric field of microwaves, but also the magnetic field of microwaves. Besides the ability to detect microwave intensity, the spintronic sensors also have the ability to detect microwave phase on-chip, which has been recently demonstrated in a spin dynamo and an MTJ, respectively.

Hindering the development of spin-diode based detectors is their requirement of a static magnetic field to produce the ferromagnetic resonances required for their operation, typically on the order of a few 10 mT to a few 100 mT depending on the microwave frequency. The single frequency operating mode of these detectors is also in contradiction with the generally broadband requirements of microwave imaging; thus technology allowing non-resonant imaging of magnetization motion in ferromagnetic materials must be developed Embodiments of the invention demonstrate an advancement in non-resonant microwave imaging using an on-chip spintronic sensor based on an MTJ, where the non-resonant Seebeck rectification results in a sensitivity of 1-10 mV/mW, at least two orders of magnitude higher than that in a spin dynamo. This allows the sensor to perform far-field imaging despite the fact that the intensity of scattered microwaves decreases quadratically with distance.

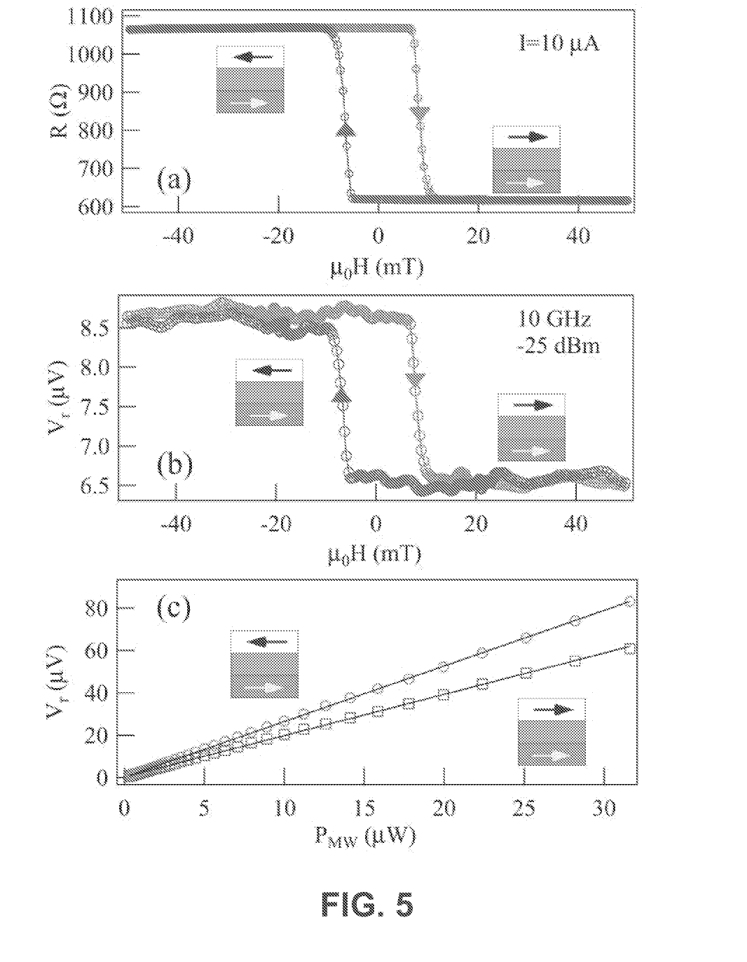

The key element of the spintronic microwave sensor is an MTJ structure. The MTJs are grown on an Si substrate covered with 200 nm SiO 2 and contain the following layers: PtMn(20 nm)/CoFe(2.27 nm)/Ru(0.8 nm)/CoFeB(2.2 nm)/CoFe(0.525 nm)/MgO(1.2 nm)/CoFeB(2.5 nm). The buffer and capping layer are TaN and Ta, respectively. This multilayer structure was further patterned into elliptical shapes with different dimensions and aspect ratios, but with the pinning direction always along the long axis. Applying a static magnetic field along their easy axis, the MTJs show single domain magnetization reversal, as seen in FIG. 5(a) for a sample with long and short axes of 190 and 100 nm, respectively.

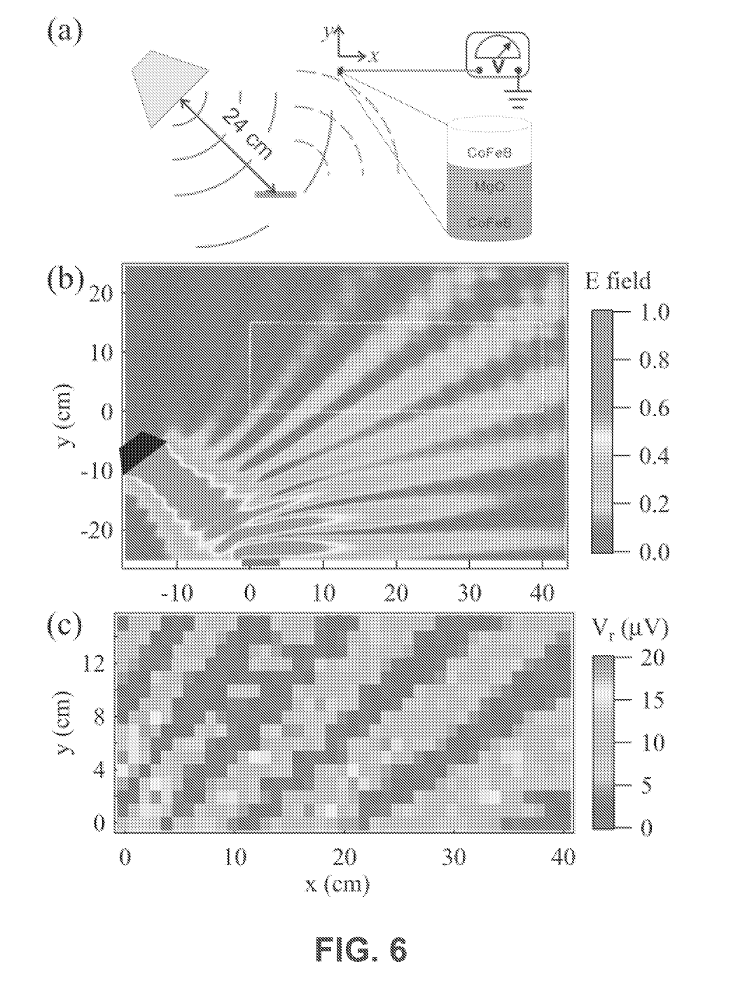

Studies have found that thermal effects within MTJs can be significant, with giant Seebeck coefficients as high as S=1 mV/K reported at room temperature. When placed under microwave radiation, the components of an MTJ are subject to Joule heating by the microwave current (i) produced by the incident radiation. Due to the asymmetry of the internal structure of the MTJ, this increase in temperature will result in a temperature gradient, ΔT, being produced across the MgO barrier layer; this gradient produces a dc voltage as Vᵣ=S·Δ∝i² as detailed discussion in Eq. (2) and (3). This dc voltage, Vᵣ, is a result of Seebeck rectification and, as shown in FIG. 5(b), it is strongest when the MTJ is in an anti-parallel (AP) state. As shown in FIG. 5(c), Vᵣ is linearly sensitive to the microwave power incident on the MTJ by a direct microwave current injection, with sensitivities of 2.6 and 2.0 mV/mW measured for the AP and P states, respectively. The sensitivity of an MTJ is dependent on its size, with smaller MTJs generally having a higher sensitivity. It has also been found that the sensitivity of the MTJ remains constant for Vᵣ values as high as 1 mV (not shown). In contrast to the linear Vᵣ caused by non-resonant Seebeck rectification, the resonant Vᵣ (dependent on the precession cone angle) shows a sub-linear microwave power dependence at high levels due to nonlinear spin dynamics. In our experiment, unless otherwise specified, the MTJ used was kept in the AP configuration and a horn antenna was used to channel 100 mW of microwaves towards the target. Because microwave intensity decreases quadratically with distance, Vᵣ and the output microwave power have a ratio on the order of 1 μV/mW when the sensor is placed about 25 cm away from the horn antenna. A standard lock-in technique was used which fully modulated the microwave power amplitude with a 8.33 kHz square wave, enhancing the signal/noise ratio and enabling Seebeck rectified voltages as weak as 20 nV to be detected. To demonstrate the capability of a spintronic sensor to detect a microwave field, we have used it to measure a spatial distribution of microwave power. A detailed layout of the apparatus is shown in FIG. 6(a), where a standard C-band (4-6 GHz) horn antenna connected to a microwave generator was used to emit microwaves onto a flat aluminium (Al) strip (width=5.08 cm, thickness=0.64 cm) positioned at a fixed 24 cm distance from the horn and angled to ensure a 45 degree incident angle for the microwaves. A spintronic microwave sensor connected to a Lock-in amplifier was then tasked with detecting the microwave field reflected from the aluminium strip.

Like any optical wave, microwaves obey the standard laws of optics and thereby interact with surfaces in the processes of reflection, refraction, diffraction, etc. Even though the environment our apparatus was placed in was large enough to emulate free space, the microwave propagation pattern seen was still very complex due to the fact that the microwaves reflected by the aluminium strip will interfere with the waves in free space [as shown in FIG. 6(a)]. In addition, due to the aluminium strip's finite size, diffraction effects from its edges cannot be neglected. Despite these complexities, the spatial distribution of the reflected and incident microwave fields can be simulated using COMSOL Multiphysic as shown in FIG. 6(b), where the incident microwave beam emitted from the horn antenna is assumed to consist of plane waves. In this simulated pattern we see that the incident microwave beam has the strongest intensity (as expected), in addition to an interesting series of side lobes seen connected to the incident beam.

Scanning the microwave field with the sensor in both the x and y directions, a two dimensional image of the field can be generated [as shown in FIG. 6(c)]. The area scanned [dotted lines in FIG. 6(b)] was selected to minimize the effects of microwaves scattering off the sensor and its holder. The locations of the minimum and maximum microwave intensities, which are measured as locations of maximum and minimum induced Vᵣ by our detector and shown in FIG. 6(c), are seen to shift along both the x and y axes and generally agree with the simulated pattern. Simulated and measured wave patterns at different frequencies feature the same characteristics as seen in FIG. 6(b) and FIG. 6(c), with the space between lobes appearing to increase as the frequency decreases. In all cases the reflected waves behave as a standing wave with an intensity that decays quadratically with distance from the strip. It is notable that the wavelength of the microwaves used in our measurements is about λ=5˜7.5 cm, which is comparable to or larger than the width of the aluminium strip.

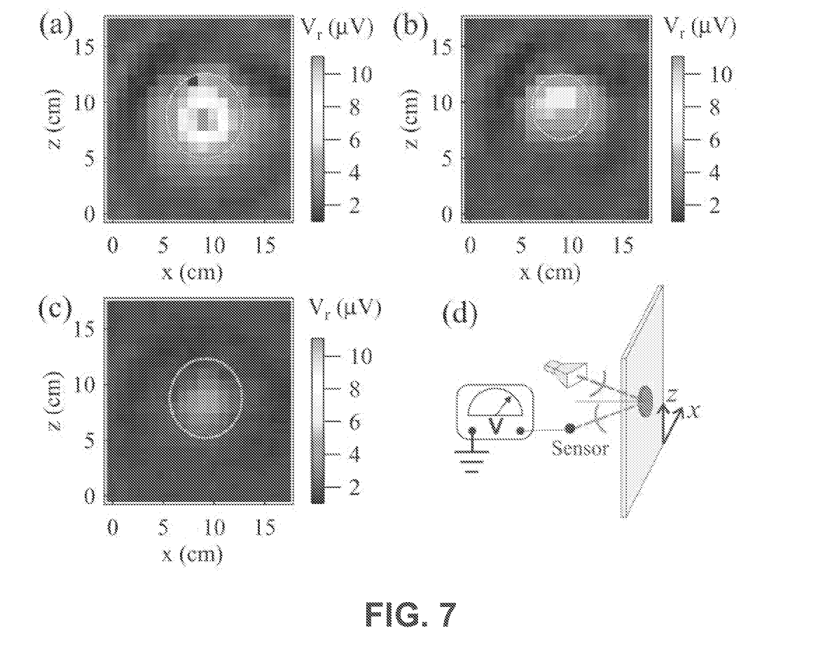

Using a horn antenna as a transmitter and an MTJ based sensor as a receiver, we also demonstrate that nondestructive imaging can be achieved using microwave reflection imaging. As shown in FIG. 7(d), a standard X-band horn antenna (8-12 GHz) is placed 15 cm away from the surface and positioned so that the microwaves will be incident upon the surface at an angle of 45 degrees, while the MTJ sensor is placed across from the horn a distance of 15 cm from the surface and positioned so that waves from the horn which reflect off the surface at an angle of 45 degrees will travel directly to the sensor. The surface being imaged consists of a 50 cm×50 cm sheet of plywood 3.0 cm thick with a circular Al disk (diameter=7.12 cm, thickness=0.32 cm) fastened to the side opposite that of the horn and detector. Therefore the plywood hides the Al disc from the sensor. Scanning the surface in the x-z plane, we can record the microwave field distribution scattered by the surface using the MTJ sensor. As shown in FIG. 7(a), the distribution of the Vᵣ induced in the sensor by the reflected microwave field is significantly influenced by the presence of the Al disk, as where the disk is mounted on the surface an abnormal area clearly appears in the mapped Vᵣ distribution (where the dotted line in FIG. 7(a) indicates the position of the disk).

This proposed technique for using spintronic microwave sensors to perform far-field microwave imaging is not only able to non-destructively detect hidden objects, but may also possess the capability to determine the size and composition of these hidden objects. In addition to the 7.12 cm diameter Al disk mentioned previously, we have also performed far-field imaging on an Al disk with a 5.08 cm diameter (FIG. 7(b)) and an acetal disk with a 7.12 cm diameter (FIG. 7(c)). The colour intensity scales in FIGS. 7(a)-(c) are the same to allow these images to be systematically compared. An interesting feature of FIG. 7(c) is that the dielectric constants of acetal (∈r=3.7) and air (∈r=1) can be clearly differentiated by using this microwave imaging technique.

In summary, the high sensitivity of MTJ based spintronic microwave sensors of the present invention enable direct spatial measurements of scattered microwave field distributions. The capability to non-destructively detect hidden objects in the far-field range suggests a promising approach in noncontact and non-destructive microwave imaging methodology for use in industrial, chemical and biological applications can be developed by using spintronic technologies.

All of the methods disclosed and claimed herein can be made and executed without undue experimentation in light of the present disclosure. While the apparatus and methods of this invention have been described in terms of preferred embodiments, it will be apparent to those of skill in the art that variations may be applied to the methods and in the steps or in the sequence of steps of the method described herein without departing from the concept, spirit and scope of the invention. In addition, modifications may be made to the disclosed apparatus and components may be eliminated or substituted for the components described herein where the same or similar results would be achieved. All such similar substitutes and modifications apparent to those skilled in the art are deemed to be within the spirit, scope, and concept of the invention as defined by the appended claims.

1. An thermoelectric device comprising:
a substrate, and
a Magnetic Tunneling Junctions (MTJ) patterned from a ferromagnetic multilayer structure grown on the substrate, the MTJ comprising a plurality of thermoelectric layers configured such that a non-linearity between a tunneling current (I) and a voltage (V) on the MJT is induced by heat dissipation of the tunneling current which modifies a voltage profile of the MJT and breaks the temperature symmetry of an MTJ via thermoelectric coupling, such that a measurement of a Seebeck coefficient S and microwave Seebeck rectification exhibited by the MTJ is provided without requiring an external heating source.

2. The thermoelectric device of claim 1, wherein the MJT comprises a plurality of Thomson Thermoelectric Conductor (TTC) elements.

3. The thermoelectric device of claim 1, wherein at least two of the plurality of thermoelectric layers comprises ferromagnetic layer such as CoFeB.

4. The thermoelectric device of claim 1, wherein at least one of the plurality of thermoelectric layers comprises tunneling barrier layer such as MgO.

5. A magnetoelectric device comprising:
a substrate, and
a Magnetic Tunneling Junction (MTJ), the MTJ comprising of a plurality of magnetoelectric layers configured such that a non-linearity between a tunneling current (I) and a voltage (V) on the MTJ is induced by coupling between magnetization and conductivity in the MTJ, breaking the spin-polarization symmetry of the MTJ.

6. The magnetoelectric device of claim 5, wherein the MTJ is configured to allow microwave rectification.

7. The magnetoelectric device of claim 5, wherein at least two of the plurality of magnetoelectric layers comprises a ferromagnetic layer.

8. The magnetoelectric device of claim 7, wherein the ferromagnetic layer is comprised of CoFeB.

9. The magnetoelectric device of claim 5, wherein at least one of the plurality of magnetoelectric layers comprises a tunneling barrier layer.

10. The magnetoelectric device of claim 9, wherein the tunneling barrier layer is comprised of MgO.

11. The magnetoelectric device of claim 5, wherein the first and second ferromagnetic layer are comprised of different materials or alloys having different compositions.
